(19) United States
(12) Patent Application Publication
(10) Pub. No.: US 2026/0337064 A1
(43) Pub. Date: Oct. 29, 2026

(54) TREATMENT SYSTEM AND METHOD FOR ZERO-DISCHARGE OF PHOTOVOLTAIC WASTEWATER

(71) Applicant: Greentech Environment Co., Ltd., Beijing (CN)

(72) Inventors: Mengyuan DUAN, Beijing (CN); Zehua LI, Beijing (CN); Kai SUN, Beijing (CN); Pengchuan ZHANG, Beijing (CN); Xikun ZHU, Beijing (CN); Liyan ZHANG, Beijing (CN)

(21) Appl. No.: 19/700,731

(22) Filed: Jun. 8, 2026

(30) Foreign Application Priority Data
Dec. 2, 2025 (CN) 202511796754.7

(51) Int. Cl. C02F 1/463; C02F 1/44; C02F 1/52; C02F 103/34; C02F 103/40; H10F 71/00

(52) U.S. Cl. CPC C02F 1/463; C02F 1/441; C02F 1/444; H10F 71/137; C02F 2001/5218; C02F 2103/346; C02F 2103/40; C02F 2201/005; C02F 2209/003; C02F 2301/08; C02F 2303/185

(57) ABSTRACT

A treatment system and method for zero-discharge of photovoltaic wastewater are provided. The treatment system includes a dilute acid wastewater treatment device, a dilute alkaline wastewater treatment device and a neutralized concentrated water filtration device. The dilute acid wastewater treatment device includes a dilute acid wastewater filtration unit, an acid circuit concentrated water conditioning unit, a calcium fluoride crystallization unit and a calcium bicarbonate crystallization unit connected in sequence. The dilute acid wastewater treatment device further includes an adjustment pipeline, which is connected upstream of the calcium fluoride crystallization unit, between the calcium fluoride crystallization unit and the calcium bicarbonate crystallization unit, and downstream of the calcium bicarbonate crystallization unit. The dilute alkaline wastewater treatment device includes a dilute alkaline wastewater filtration unit and a silicic acid crystallization unit connected in sequence.

### CROSS-REFERENCE TO RELATED APPLICATIONS

This application claims the benefit of priority from Chinese Patent Application No. 202511796754.7, filed on Dec. 2, 2025. The content of the aforementioned application, including any intervening amendments thereto, is incorporated herein by reference in its entirety.

### TECHNICAL FIELD

This application relates to photovoltaic manufacturing, and more particularly to a treatment system and method for zero-discharge of photovoltaic wastewater.

### BACKGROUND

A solar cell (photovoltaic cell), also called solar chip or photocell, is an optoelectronic semiconductor sheet that can directly transform solar energy into electricity. Upon being exposed to a certain illuminance condition, the solar cell can instantly output a voltage, and generate a current when a closed circuit is established. From 2012 to 2023, global production of photovoltaic cells continuously increased from 38 to 644 gigawatt (GW). However, the rapid development of the photovoltaic cell industry is inevitably accompanied by a dramatic increase in the water demand and discharged wastewater.

Photovoltaic wastewater is mainly generated from the etching and texturing processes, including concentrated acid wastewater produced during the etching, concentrated alkaline wastewater produced during the texturing, dilute acid wastewater produced during acid cleaning after texturing, and dilute alkaline wastewater produced during alkaline polishing after etching. The photovoltaic wastewater features high corrosivity and poor biodegradability. Pollutants contained in the concentrated acid wastewater and dilute acid wastewater (generally exhibiting a pH of approximately 2.0-3.0) are predominated by hydrochloric acid, hydrofluoric acid, and fluorosilicic acid, along with low levels of alcohol compounds, surfactants, and suspended silica particles. Pollutants contained in the concentrated alkaline wastewater and dilute alkaline wastewater (with a pH of approximately 11.0-12.0) are predominated by silicates, sodium hydroxide, and hydrogen peroxide, along with low levels of fluorides, alcohol compounds, surfactants, and suspended silica particles. The concentrated acid wastewater and the concentrated alkaline wastewater have extremely high levels of inorganic salt pollutants, with an electrical conductivity typically reaching 10⁵ μS/cm or above. By comparison, the dilute acid wastewater and the dilute alkaline wastewater have relatively lower levels of inorganic salt pollutants, but they still exhibit a relatively high electrical conductivity (10⁴ μS/cm or above).

Considering the remarkable differences among the above four types of wastewater samples, different resource utilization strategies should be reasonably combined for separate treatment. The technical solution proposed herein is mainly intended for simultaneously realizing regeneration and reuse of dilute acid wastewater and dilute alkali wastewater as well as zero-discharge of photovoltaic wastewater.

### SUMMARY

In order to at least partially solve the above technical problems, the present disclosure provides a treatment system and method for zero-discharge of photovoltaic wastewater, by which the dilute acid wastewater and the dilute alkaline wastewater generated during the photovoltaic production process can be effectively treated and recycled, so as to reduce the level of harmful substances in the discharged water, and meet requirements of environmental protection policies.

In a first aspect, the present disclosure provides a system for treating photovoltaic wastewater, comprising:
a dilute acid wastewater treatment device;
a dilute alkaline wastewater treatment device; and
a neutralized concentrated water filtration device;
wherein the dilute acid wastewater treatment device comprises a dilute acid wastewater filtration unit, an acid circuit concentrated water conditioning unit, a dehydrator, a calcium fluoride crystallization unit, and a calcium bicarbonate crystallization unit connected in sequence; the dilute acid wastewater treatment device further comprises a adjustment pipeline, and the adjustment pipeline is configured for connection to upstream of the calcium fluoride crystallization unit, connection between the calcium fluoride crystallization unit and the calcium bicarbonate crystallization unit, and connection to downstream of the calcium bicarbonate crystallization unit;
the dilute alkaline wastewater treatment device comprises a dilute alkaline wastewater filtration unit and a silicic acid crystallization unit connected in sequence; and
the neutralized concentrated water filtration device is connected downstream of the calcium bicarbonate crystallization unit and the silicic acid crystallization unit.

In an embodiment, the dilute acid wastewater filtration unit comprises a first inlet pipe, a first backwashable filter, a second inlet pipe, and a first reverse osmosis unit connected in sequence; wherein the first inlet pipe and/or the second inlet pipe is provided with a first booster pump.

In an embodiment, the acid circuit concentrated water conditioning unit comprises a conditioning tank and a calcium carbonate dosing tank; a concentrated water side of the first reverse osmosis unit is connected with the conditioning tank via a first outlet pipe; and the calcium carbonate dosing tank is connected with the conditioning tank, and is configured to add calcium carbonate into the conditioning tank.

In an embodiment, the dehydrator is provided with a first liquid inlet, a first liquid outlet, and a return port; the conditioning tank is connected with the first liquid inlet via a second outlet pipe; the first liquid outlet is connected with the calcium fluoride crystallization unit via a third outlet pipe; and the return port is connected with the calcium carbonate dosing tank via a return pipe; and the calcium fluoride crystallization unit is connected with the calcium bicarbonate crystallization unit via a fourth outlet pipe; a first check valve is provided on an inlet end of the fourth outlet pipe; the calcium bicarbonate crystallization unit is connected with the neutralized concentrated water filtration device via a fifth outlet pipe; and a second check valve is provided on an inlet end of the fifth outlet pipe.

In an embodiment, the neutralized concentrated water filtration device comprises an electrocoagulation sedimentation tank, an ultrafiltration unit, a second reverse osmosis unit, and an evaporative crystallizer connected in sequence; a second booster pump is provided between the ultrafiltration unit and the second reverse osmosis unit; and the evaporative crystallizer is connected with a concentrated water side of the second reverse osmosis unit.

In an embodiment, the adjustment pipeline comprises a first branch pipe, a second branch pipe, a flow diversion pipe, a first valve, a second valve, a third valve, and a fourth valve; an inlet end of the first branch pipe communicates with the third outlet pipe; an outlet end of the first branch pipe communicates with a first end of the flow diversion pipe and an inlet end of the second branch pipe; a second end of the flow diversion pipe communicates with the fourth outlet pipe; and an outlet end of the second branch pipe communicates with the fifth outlet pipe; and
the first valve is provided on the first branch pipe; the second valve is provided on the second branch pipe; the third valve is provided on the third outlet pipe, and is located downstream of the inlet end of the first branch pipe; the fourth valve is provided on the fourth outlet pipe, and is located downstream of the second end of the flow diversion pipe.

In an embodiment, the third outlet pipe is provided with a first fluoride detector and a first calcium ion detector; and the first fluoride detector and the first calcium ion detector are located upstream of the inlet end of the first branch pipe; and
the fourth outlet pipe is provided with a second calcium ion detector; and the second calcium ion detector is located upstream of the first check valve.

In an embodiment, the system further comprises a regenerated water tank; wherein a permeate side of the first reverse osmosis unit communicates with the regenerated water tank via a first permeate pipe; a permeate side of the second reverse osmosis unit communicates with the regenerated water tank via a second permeate pipe; and
the dilute alkaline wastewater filtration unit comprises a dilute alkaline wastewater conditioning subunit, a second backwashable filter and a nanofiltration subunit; a third booster pump is provided between the second backwashable filter and the nanofiltration subunit; a permeate side of the nanofiltration subunit communicates with the regenerated water tank via a third permeate pipe; and a concentrated water side of the nanofiltration subunit is connected with the silicic acid crystallization unit.

In an embodiment, a top of the conditioning tank communicates with the silicic acid crystallization unit via a gas supply pipe.

In a second aspect, the present disclosure provides a method for treating photovoltaic wastewater, the method being performed based on the system above, and the method comprising:
(S1) measuring, by the first fluoride detector, a fluoride content of the of the dehydrator as F₁ mg/L; measuring, by the first calcium ion detector, a first calcium ion content of the of the dehydrator as C₁ mg/L; and measuring, by the second calcium ion detector, a second calcium ion content of the calcium fluoride crystallization unit as C₂ mg/L;
(S2) when F₁<5.0, closing the third valve, and opening the first valve; and stopping the calcium fluoride crystallization unit;
(S3) when F₁≥5.0, opening the third valve, and closing the first valve; and starting the calcium fluoride crystallization unit;
(S4) when the second calcium ion detector does not issue an empty-pipe alarm and C₂<330, closing the fourth valve, and opening the second valve; and stopping the calcium bicarbonate crystallization unit;
when the second calcium ion detector does not issue the empty-pipe alarm and C₂≥330, opening the fourth valve, and closing the second valve; and starting the calcium bicarbonate crystallization unit;
when the second calcium ion detector issues the empty-pipe alarm and C₁<330+10F₁/19, closing the fourth valve, and opening the second valve; and stopping the calcium bicarbonate crystallization unit; and
when the second calcium ion detector issues the empty-pipe alarm and C₁≥330+10F₁/19, opening the fourth valve, and closing the second valve; and starting the calcium bicarbonate crystallization unit.

Compared to the prior art, the present disclosure has the following beneficial effects.
(1) Complete resource recovery of photovoltaic wastewater and valuable substances therein is realized, while producing high-quality reclaimed water that can be reused in photovoltaic cell production lines, as well as inorganic salt products including silica, calcium fluoride, calcium bicarbonate, and sodium chloride.
(2) Acid-base neutralization and organic pollutant removal is achieved while substantially eliminating the need for biological treatment units, thereby significantly reducing the generation of solid wastes such as activated sludge and precipitated sludge.

### BRIEF DESCRIPTION OF THE DRAWINGS

The accompanying drawings herein are incorporated into the specification and form a part of the specification to illustrate the embodiments of the present disclosure. The accompanying drawings together with the specification are used to explain the principles of the present disclosure.

In order to illustrate the technical solutions of this application or the prior art more clearly, the accompanying drawings required in the description of embodiments or the prior art will be briefly introduced below. It is obvious that for those of ordinary skill in the art, other relevant accompanying drawings can also be obtained according to these drawings without making creative effort.

FIG. 1 is a structural diagram of a system for treating photovoltaic wastewater according to an embodiment of the present disclosure.

FIG. 2 is a flow chart of a method for treating photovoltaic wastewater according to an embodiment of the present disclosure.

In the FIGS.: 1, dilute acid wastewater filtration unit; 101, first inlet pipe 102, first backwashable filter; 103, first reverse osmosis unit; 104, second inlet pipe;

2, acid circuit concentrated water conditioning unit; 201, conditioning tank; 202, calcium carbonate dosing tank;

3, calcium fluoride crystallization unit;

4, calcium bicarbonate crystallization unit;

5, dilute alkaline wastewater filtration unit; 501, dilute alkaline wastewater conditioning subunit; 502, second backwashable filter; 503, nanofiltration subunit;

6, silicic acid crystallization unit;

7, neutralized concentrated water filtration device; 701, electrocoagulation sedimentation tank; 702, ultrafiltration unit; 703, second reverse osmosis unit; 704, evaporative crystallizer;

8, dehydrator;

9, first calcium ion detector;

10, first fluoride detector;

11, second calcium ion detector;

12, first branch pipe; 121, first valve;

13, second branch pipe; 131, second valve;

14; third outlet pipe; 141, third valve;

15, fourth outlet pipe; 151, fourth valve;

16, first outlet pipe;

17, second outlet pipe;

18, return pipe;

19, fifth outlet pipe;

20, third permeate pipe;

21, regenerated water tank;

22, first permeate pipe;

23, second permeate pipe;

24, gas supply pipe; and

25, flow diversion pipe.

### DETAILED DESCRIPTION OF EMBODIMENTS

To make the above objects, features and advantages of the present disclosure more clearly, the present disclosure will be further described below. It should be noted that the embodiments of the present disclosure and features therein can be combined with each other without conflicts.

The following description elaborates on many specific details to facilitate a full understanding of the present disclosure, but the present disclosure can also be implemented in other ways different from those described herein. It is obvious that the embodiments herein are only part of the embodiments of the present application, rather than all embodiments.

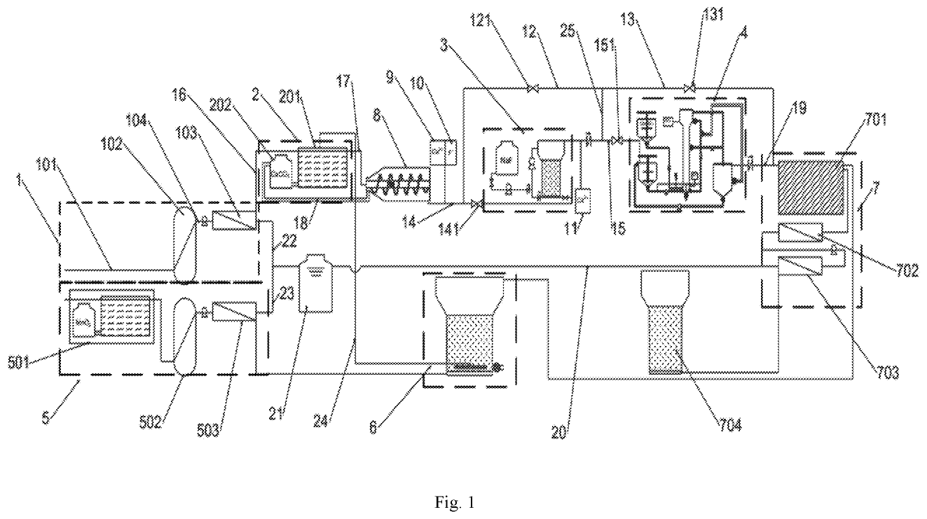

Referring to FIG. 1, the embodiment of the present disclosure provides system for treating photovoltaic wastewater. The system includes a dilute acid wastewater treatment device, a dilute alkaline wastewater treatment device and a neutralized concentrated water filtration device 7. The dilute acid wastewater treatment device includes a dilute acid wastewater filtration unit 1, an acid circuit concentrated water conditioning unit 2, a dehydrator 8, a calcium fluoride crystallization unit 3, a calcium bicarbonate crystallization unit 4, an adjustment pipeline, where the dilute acid wastewater filtration unit 1, the acid circuit concentrated water conditioning unit 2, the calcium fluoride crystallization unit 3, the calcium bicarbonate crystallization unit 4 are connected in sequence. The adjustment pipeline is configured for connection to upstream of the calcium fluoride crystallization unit 3, connection between the calcium fluoride crystallization unit 3 and the calcium bicarbonate crystallization unit 4, and connection to downstream of the calcium bicarbonate crystallization unit 4. The adjustment pipeline is configured to selectively direct a solution flowing out of the acid circuit concentrated water conditioning unit 2 through the calcium fluoride crystallization unit 3 and/or the calcium bicarbonate crystallization unit 4. The dilute alkaline wastewater treatment device includes a dilute alkaline wastewater filtration unit 5 and a silicic acid crystallization unit 6 connected in sequence. The neutralized concentrated water filtration device 7 is connected downstream of the calcium bicarbonate crystallization unit 4 and the silicic acid crystallization unit 6. The neutralized concentrated water filtration device 7 is configured to perform sedimentation and filtration on crystallized acidic and alkaline liquids.

In an embodiment, dilute acid wastewater generated during photovoltaic production process is first introduced into the dilute acid wastewater filtration unit 1 to remove suspended particles such as silicon dioxide from the dilute acid wastewater, and then is introduced into the acid circuit concentrated water conditioning unit 2 to adjust a pH of the dilute acid wastewater, so as to meet an optimal condition for subsequent crystallization reactions. The adjustment pipeline has three modes. Exemplarily, in a first mode: the calcium fluoride crystallization unit 3 and the calcium bicarbonate crystallization unit 4 are connected in sequence, and wastewater treated by the acid circuit concentrated water conditioning unit 2 passes through the calcium fluoride crystallization unit 3 and the calcium bicarbonate crystallization unit 4 for crystallization, and then is introduced into the neutralized concentrated water filtration device 7. In a second mode: the calcium fluoride crystallization unit 3 is connected, and the calcium bicarbonate crystallization unit 4 is closed, the wastewater treated by the acid circuit concentrated water conditioning unit 2 passes through the calcium fluoride crystallization unit 3 for crystallization and then is directly introduced into the neutralized concentrated water filtration device 7. In a third mode: the calcium fluoride crystallization unit 3 is closed, and the calcium bicarbonate crystallization unit 4 is connected, the wastewater treated by the acid circuit concentrated water conditioning unit 2 bypasses the calcium fluoride crystallization unit 3, enters the calcium bicarbonate crystallization unit 4 for crystallization, and then is directly introduced into the neutralized concentrated water filtration device 7. The optimal mode is selected according to parameters monitored in real time, such as a pH of the dilute acid wastewater, a concentration of fluoride ion and a concentration of calcium ion, during the wastewater treatment process, so as to ensure treatment performance and efficiency.

In an embodiment, the adjustment pipeline includes a first branch pipe 12, a second branch pipe 13, a flow diversion pipe 25, a first valve 121, a second valve 131, and a third valve 141. The first branch pipe 12 is provided with one first inlet end and two first outlet ends. The first inlet end is connected to an upstream pipe of the calcium fluoride crystallization unit 3. The flow diversion pipe 25 is connected between one of the two first outlet ends and an upstream pipe of the calcium bicarbonate crystallization unit 4. The second branch pipe 13 is connected between the other one of the two first outlet ends and a downstream pipe of the calcium bicarbonate crystallization unit 4. The first valve 121 is provided on the first branch pipe 12. The second valve 131 is provided on the second branch pipe 13. The third valve 141 is provided on the upstream pipe of the calcium fluoride crystallization unit 3.

In an embodiment, the upstream pipe of the calcium fluoride crystallization unit 3 includes a third outlet pipe 14. The third outlet pipe 14 is connected between the acid circuit concentrated water conditioning unit 2 and the calcium fluoride crystallization unit 3. The first inlet of the first branch pipe 12 communicates with the third outlet pipe 14. The first valve 121 is provided on the first branch pipe 12. The third valve 141 is provided on the third outlet pipe 14. When the first valve 121 is open and the third valve 141 is closed, the first branch pipe 12 is open and the calcium fluoride crystallization unit 3 is closed. When the first valve 12 is closed and the third valve is open, the first branch pipe 12 is closed and the calcium fluoride crystallization unit 3 is open. A first end of the flow diversion pipe 25 is connected with the one of the two first outlet ends of the first branch pipe 12, and a second end of the flow diversion pipe 25 is connected with the upstream pipe of the calcium bicarbonate crystallization unit 4, so as to allow the solution to bypass the calcium fluoride crystallization unit 3 and directly enter the calcium bicarbonate crystallization unit 4. The upstream pipe of the calcium bicarbonate crystallization unit 4 includes a fourth outlet pipe 15. The fourth outlet pipe 15 is provided with a fourth valve 151. When the fourth valve 151 is open, the calcium bicarbonate crystallization unit 4 is open. When the fourth valve 151 is closed, the calcium bicarbonate crystallization unit 4 is closed. A first end of the second branch pipe 13 is connected with the other one of the two first outlet ends, and a second end of the second branch pipe 13 is connected with the downstream pipe of the calcium bicarbonate crystallization unit 4. In an embodiment, the downstream pipe of the calcium bicarbonate crystallization unit 4 includes a fifth outlet pipe 19. The fifth outlet pipe 19 is connected between the calcium bicarbonate crystallization unit 4 and the neutralized concentrated water filtration device 7. When the second valve 131 is open, the solution bypasses the calcium bicarbonate crystallization unit 4 and directly enters the neutralized concentrated water filtration device 7.

In an embodiment, the dilute acid wastewater filtration unit 1 includes a first inlet pipe 101, a first backwashable filter 102, a second inlet pipe 104, and a first reverse osmosis unit 103 connected in sequence. The first inlet pipe 101 and/or the second inlet pipe 104 is provided with a first booster pump.

A first end of the first inlet pipe 101 is connected with a source of the dilute acid wastewater, and a second end of the first inlet pipe 101 is connected with an inlet of the first backwashable filter 102, so as to convey raw dilute acid wastewater to the dilute acid wastewater filtration unit 1. The first backwashable filter 102 is configured to remove suspended large particle pollutants, such as silicon dioxide particles and small amounts of solid impurities, so as to protect the subsequent precision first reverse osmosis unit 103. A first end of the second inlet pipe 104 is connected with an outlet of the first backwashable filter 102, and a second end of the first end of the second inlet pipe 104 is connected with an inlet of the first reverse osmosis unit 103. The second inlet pipe 104 is configured to convey preliminarily filtered wastewater to the first reverse osmosis unit 103. The first reverse osmosis unit 103 is configured to further retain colloids and dissolved impurities, and produce high-quality reclaimed water.

The first reverse osmosis unit 103 includes a reverse osmosis membrane element, a pressure vessel, and a sealing ring. The reverse osmosis membrane element is made of inert materials such as sulfonated polyethersulfone and polyvinylidene fluoride, which has extremely high chemical stability to prevent corrosion and degradation of the reverse osmosis membrane element. Other components, such as the pressure vessel and the sealing ring, are made of acid-resistant materials such as SS316L stainless steel. The SS316L stainless steel contains molybdenum and has far better corrosion resistance than ordinary stainless steel, such as 304 stainless steel, and the SS316L stainless steel can prevent an inner wall of the pressure vessel and the sealing ring from being corroded and leaking due to the acid solution.

In an embodiment, the acid circuit concentrated water conditioning unit includes a conditioning tank 201 and a calcium carbonate dosing tank 202. The conditioning tank 201 is connected with the first reverse osmosis unit 103 via a first outlet pipe 16. The calcium carbonate dosing tank 202 is connected with the conditioning tank 201, and is configured to add conditioning tank 201 into the conditioning tank 201.

An inlet of the conditioning tank 201 is connected with an outlet of the first reverse osmosis unit 103 via the first outlet pipe 16. An outlet of the conditioning tank 201 is connected with the upstream pipe of the calcium fluoride crystallization unit 3. The conditioning tank 201 is configured as a reaction vessel for pH adjustment, providing space for mixing and reaction of the wastewater with calcium carbonate. The calcium carbonate dosing tank 202 is connected with the conditioning tank 201 via a dosing pipeline including a dosing pump and a flow meter, typically accessing a middle or bottom of a tank body to ensure uniform mixing. The calcium carbonate dosing tank 202 is configured to store solid calcium carbonate or a calcium carbonate suspension solution, and precisely add them into the conditioning tank 201.

The conditioning tank 201 is typically provided with a stirring device, such as a mechanical stirring paddle and an aeration device, and an online pH monitor. The dosing pipeline is provided with a dosing pump and a flow control valve. The online pH monitor is configured to provide real-time feedback of the pH of the water quality and is interlocked with the dosing pump to adjust a dosing amount.

In an embodiment, the dehydrator 8 is provided between the conditioning tank 201 and the calcium fluoride crystallization unit 3. The dehydrator 8 is provided with a first liquid inlet, a first liquid outlet, and a return port. The first liquid inlet communicates with the outlet of the conditioning tank 201 via a second outlet pipe 17. The first liquid outlet communicates with the calcium fluoride crystallization unit 3 via the third outlet pipe 14. The return port communicates with the calcium carbonate dosing tank 202 via a return pipe 18.

In an embodiment, the first liquid inlet of the dehydrator 8 communicates with the outlet of the conditioning tank 201 via the second outlet pipe 17. The first liquid outlet communicates with the calcium fluoride crystallization unit 3 via the third outlet pipe 14. The return port communicates with the calcium carbonate dosing tank 202 via the return pipe 18. An outlet of the dehydrator 8 is provided with a solid-liquid separation screen or filter membrane. The return pipe 18 is provided with a conveying pump and a filter. The second outlet pipe 17 is provided with a flow control valve. The dehydrator 8 adopts centrifugal dewatering, filter press dewatering, or other ways to separate and recover unreacted calcium carbonate precipitate from the conditioning tank 201, and the unreacted calcium carbonate precipitate flows out through the return port and is sent back to the calcium carbonate dosing tank 202 via the return pipe 18 which is pressurized by a submersible pump, thereby achieving recycling.

In an embodiment, the third outlet pipe 14 is connected with a first fluoride detector 10 and/or a first calcium ion detector 9. The fourth outlet pipe 15 is connected with a second calcium ion detector 11.

In an embodiment, the neutralized concentrated water filtration device 7 includes an electrocoagulation sedimentation tank 701, an ultrafiltration unit 702, a second reverse osmosis unit 703, and an evaporative crystallizer 704 connected in sequence. Two inlets and one outlet of the electrocoagulation sedimentation tank 701 are provided. One of the two inlets of the electrocoagulation sedimentation tank 701 is connected with an outlet of the calcium bicarbonate crystallization unit 4 via the fifth outlet pipe 19, and the other one of the two inlets of the electrocoagulation sedimentation tank 701 is connected with an outlet of the silicic acid crystallization unit 6. The outlet of the electrocoagulation sedimentation tank 701 is connected with the ultrafiltration unit 702. The electrocoagulation sedimentation tank 701 generates metal cations such as ferric ions or aluminum ions through electrode electrolysis, which combine with hydroxide ions mainly from alkaline circuit concentrated water to form water-insoluble ferric hydroxide or aluminum hydroxide flocs. positively charged flocs capture negatively charged impurities in the wastewater through adsorption bridging, forming easily settleable “alumen ustum”, thereby achieving removal of residual impurities such as fluoride ions, fluorosilicate ions, silicate ions, and silica colloids.

The ultrafiltration unit 702 is configured to retain fine flocs, colloids, and macromolecular organics that are not completely precipitated in the electrocoagulation sedimentation tank 701, thereby preventing these impurities from entering the second reverse osmosis unit 703 and scratching or blocking the reverse osmosis membrane. The second reverse osmosis unit 703 is configured to retain residual dissolved inorganic salt ions, such as Na⁺ and Cl⁻.

The evaporative crystallizer 704 is configured to evaporate reverse osmosis concentrated water by steam heating or heat pump heating, so that salts, such as sodium chloride, crystallize out after reaching saturation concentration, thereby achieving zero discharge and full resource recovery of valuable substances from the wastewater.

In an embodiment, the system further includes a regenerated water tank 21. The first reverse osmosis unit 103 communicates with the regenerated water tank 21 via a first permeate pipe 22. The second reverse osmosis unit 703 communicates with the regenerated water tank 21 via a third permeate pipe 20. The dilute alkaline wastewater filtration unit 5 includes a dilute alkaline wastewater conditioning subunit 501, a second backwashable filter 502 and a nanofiltration subunit 503. The nanofiltration subunit 503 communicates with the regenerated water tank 21 via a second permeate pipe 23.

The regenerated water tank 21 is configured to store compliant reclaimed water, so as to achieve recycling of water resources. Water generated by the first reverse osmosis unit 103, the second reverse osmosis unit 703 and the nanofiltration subunit 503 is all introduced into the regenerated water tank 21 for storage. The dilute alkaline wastewater conditioning subunit 501 adds a manganese dioxide catalyst into a dilute alkaline wastewater to catalyze self-oxidation-reduction reaction of hydrogen peroxide, so as to decompose it into oxygen and water, thereby removing hydrogen peroxide.

The reverse osmosis membrane element is made of inert materials such sulfonated polyethersulfone and polyvinylidene fluoride, and is coated with an alkali-resistant polymer such as polyvinyl alcohol as a protective layer. The nanofiltration subunit 503 utilizes a dual mechanism of “membrane pore size sieving+charge repulsion” to retain colloids and dissolved impurities, thereby producing the high-quality reclaimed water.

In an embodiment, a top of the conditioning tank 201 is connected with the silicic acid crystallization unit 6 via a gas supply pipe 24. The acid circuit concentrated water conditioning unit 2 achieves acid removal through a reaction of carbonate with hydrogen ion, and carbon dioxide generated by the reaction is supplied via the gas supply pipe 24 to the silicic acid crystallization unit 6, where the carbon dioxide reacts with free silicates to form silicic acid crystals, and the silicic acid crystals can be calcined to produce a silica product.

The present disclosure also provides a method for treating zero-discharge of photovoltaic wastewater, the method being performed based on the system above to treat the dilute acid wastewater and the dilute alkaline wastewater generated during the photovoltaic production process, thereby meeting discharge standards required by environmental protection.

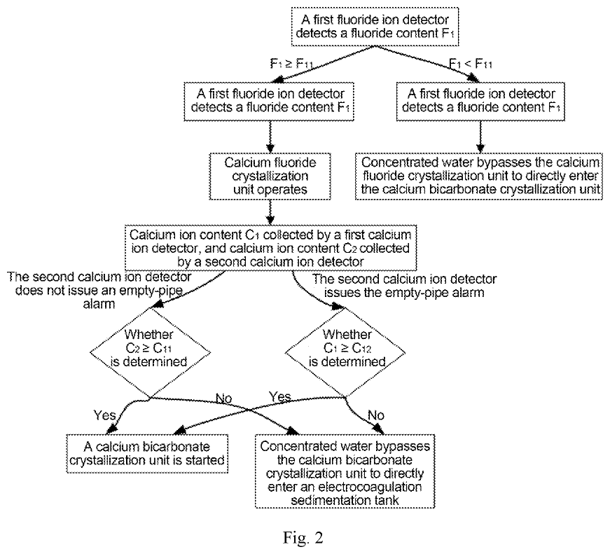

Referring to FIG. 2, the method includes the following steps.

A fluoride content F₁ at the inlet of the calcium fluoride crystallization unit 3 is detected by the first calcium ion detector 10. A first calcium ion content C₁ at the inlet of the calcium fluoride crystallization unit 3 is detected by the first calcium ion detector 9. A second calcium ion content C₂ at the outlet of the calcium fluoride crystallization unit 3 is detected by the second calcium ion detector 11.

When the F₁ is less than a first set value F₁₁, it is not necessary to start the calcium fluoride crystallization unit 3 to avoid ineffective energy consumption and reagent waste. It this way, the adjustment pipeline is switched, the third valve is closed, and the first valve is open, so that the concentrated water flowing out of the acid circuit concentrated water conditioning unit 2 bypasses the calcium fluoride crystallization unit 3.

When F₁ is larger than or equal to F₁₁, it indicates that the calcium fluoride crystallization unit 3 must be started. In this way, the adjustment pipeline is switched, the third valve is open, and the first valve is closed, so that the concentrated water flowing out of the acid circuit concentrated water conditioning unit 2 flows through the calcium fluoride crystallization unit 3.

When the second calcium ion detector 11 does not issue an empty-pipe alarm, and C₂ is less than a second set value C₁₁, it indicates that a calcium bicarbonate crystallization reaction cannot be supported. In this way, the adjustment pipeline is switched, the fourth valve is closed, and the second valve is open, so that the concentrated water flowing out of the calcium fluoride crystallization unit 3 bypasses the calcium bicarbonate crystallization unit 4 and enters the neutralized concentrated water filtration device 7.

When the second calcium ion detector 11 does not issue the empty-pipe alarm, and C₂ is larger than or equal to C₁₁, it indicates that the calcium bicarbonate crystallization reaction is supported. In this way, the adjustment pipeline is switched, the fourth valve is open, the second valve is closed, so that the concentrated water flowing out of the calcium fluoride crystallization unit 3 flows through the calcium bicarbonate crystallization unit 4.

When the second calcium ion detector 11 issues the empty-pipe alarm, and C₁ is less than a third set value C₁₂, the calcium bicarbonate crystallization reaction is not supported. In this way, the adjustment pipeline is switched, the fourth valve is closed, and the second valve is open, so that the concentrated water flowing out of the acid circuit concentrated water conditioning unit 2 bypasses the calcium bicarbonate crystallization unit 4 and enters the neutralized concentrated water filtration device 7.

When the second calcium ion detector 11 issues the empty-pipe alarm, and C₁ is larger than or equal to C₁₂, it indicates that the calcium bicarbonate crystallization reaction is supported. In this way, the adjustment pipeline is switched, the fourth valve is open, and the second valve is closed, so that the concentrated water flowing out of the acid circuit concentrated water conditioning unit 2 flows through the calcium bicarbonate crystallization unit 4.

In an embodiment, the first set value F₁₁ is 5.0 mg/L, the second set value C₁₁ is 330 mg/L, and the third set value C₁₂ is 330 mg/L+10F₁/19.

A real-time water quality monitoring system is established through the first fluoride detector 10, the first calcium ion detector 9 and the second calcium ion detector 11, with key indicators including the fluoride content F₁, the first calcium ion content C₁, and the second calcium ion content C₂ as core control bases, thereby achieving dynamic adaptation of the treatment process while efficiently controlling energy and chemical consumption.

It should be noted that the relational terms “first”, “second” and other similar terms are used only to distinguish one entity or operation from another entity or operation, rather than requiring or implying any actual relationship or order between these entities or operations. In addition, the terms “comprising”, “including” or any other variations thereof are intended to cover a non-exclusive inclusion, such that a process, method, article, or apparatus that comprises a list of elements includes not only those elements but also other elements not expressly listed, or elements inherent to such process, method, article, or apparatus. Without further limitation, an element defined by the phrase “comprising a . . . ” does not exclude the presence of additional identical elements in the process, method, article, or apparatus that includes said element.

Described above are specific embodiments of the present disclosure, which enables those skilled in the art to understand or realize the present disclosure. Various modifications to these embodiments are obvious to those skilled in the art, and general principles defined herein may be implemented in other embodiments without departing from the spirit or scope of the present disclosure. Therefore, the present disclosure will not be limited to the embodiments described herein, but rather will conform to the broadest scope consistent with the principles and novelty disclosed herein.

What is claimed is:

1. A method for treating photovoltaic wastewater using a system for treating photovoltaic wastewater, the system comprising a dilute acid wastewater treatment device, a dilute alkaline wastewater treatment device and a neutralized concentrated water filtration device; the dilute acid wastewater treatment device comprising a dilute acid wastewater filtration unit, an acid circuit concentrated water conditioning unit, a dehydrator, a calcium fluoride crystallization unit and a calcium bicarbonate crystallization unit connected in sequence; the dilute acid wastewater treatment device further comprising an adjustment pipeline, and the adjustment pipeline being configured for connection to upstream of the calcium fluoride crystallization unit, connection between the calcium fluoride crystallization unit and the calcium bicarbonate crystallization unit, and connection to downstream of the calcium bicarbonate crystallization unit, and being configured to selectively direct an outflow from the acid circuit concentrated water conditioning unit to the calcium fluoride crystallization unit, the calcium bicarbonate crystallization unit or a combination thereof; the dilute alkaline wastewater treatment device comprising a dilute alkaline wastewater filtration unit and a silicic acid crystallization unit connected in sequence; and the neutralized concentrated water filtration device being connected downstream of the calcium bicarbonate crystallization unit and the silicic acid crystallization unit; and
the method comprising:
(S1) measuring, by a first fluoride detector, a fluoride content of the dehydrator as F₁ mg/L; measuring, by a first calcium ion detector, a first calcium ion content of the dehydrator as C₁ mg/L; and measuring, by a second calcium ion detector, a second calcium ion content of the calcium fluoride crystallization unit as C₂ mg/L;
(S2) when F1<5.0, closing a third valve, and opening a first valve; and stopping the calcium fluoride crystallization unit;
(S3) when F₁≥5.0, opening the third valve, and closing the first valve; and starting the calcium fluoride crystallization unit;
(S4) when the second calcium ion detector does not issue an empty-pipe alarm and C₂<330, closing a fourth valve, and opening a second valve; and stopping the calcium bicarbonate crystallization unit;
when the second calcium ion detector does not issue the empty-pipe alarm and C₂≥330, opening the fourth valve, and closing the second valve; and starting the calcium bicarbonate crystallization unit;
when the second calcium ion detector issues the empty-pipe alarm and C₁<330+10F₁/19, closing the fourth valve, and opening the second valve; and stopping the calcium bicarbonate crystallization unit; and
when the second calcium ion detector issues the empty-pipe alarm and C₁≥330+10F₁/19, opening the fourth valve, and closing the second valve; and starting the calcium bicarbonate crystallization unit.

2. The method of claim 1, wherein the dilute acid wastewater filtration unit comprises a first inlet pipe, a first backwashable filter, a second inlet pipe and a first reverse osmosis unit connected in sequence; and the second inlet pipe is provided with a first booster pump.

3. The method of claim 2, wherein the acid circuit concentrated water conditioning unit comprises a conditioning tank and a calcium carbonate dosing tank; a concentrated water side of the first reverse osmosis unit is connected with the conditioning tank via a first outlet pipe; and the calcium carbonate dosing tank is connected with the conditioning tank, and is configured to add calcium carbonate into the conditioning tank.

4. The method of claim 3, wherein the dehydrator is provided with a first liquid inlet, a first liquid outlet and a return port; the conditioning tank is connected with the first liquid inlet via a second outlet pipe; the first liquid outlet is connected with the calcium fluoride crystallization unit via a third outlet pipe; and the return port is connected with the calcium carbonate dosing tank via a return pipe; and
the calcium fluoride crystallization unit is connected with the calcium bicarbonate crystallization unit via a fourth outlet pipe; a first check valve is provided on an inlet end of the fourth outlet pipe; the calcium bicarbonate crystallization unit is connected with the neutralized concentrated water filtration device via a fifth outlet pipe; and a second check valve is provided on an inlet end of the fifth outlet pipe.

5. The method of claim 4, wherein the neutralized concentrated water filtration device comprises an electrocoagulation sedimentation tank, an ultrafiltration unit, a second reverse osmosis unit and an evaporative crystallizer connected in sequence; a second booster pump is provided between the ultrafiltration unit and the second reverse osmosis unit; and the evaporative crystallizer is connected with a concentrated water side of the second reverse osmosis unit.

6. The method of claim 5, wherein the adjustment pipeline comprises a first branch pipe, a second branch pipe, a flow diversion pipe, the first valve, the second valve, the third valve and the fourth valve; an inlet end of the first branch pipe communicates with the third outlet pipe; an outlet end of the first branch pipe communicates with a first end of the flow diversion pipe and an inlet end of the second branch pipe; a second end of the flow diversion pipe communicates with the fourth outlet pipe; and an outlet end of the second branch pipe communicates with the fifth outlet pipe; and
the first valve is provided on the first branch pipe; the second valve is provided on the second branch pipe; the third valve is provided on the third outlet pipe, and is located downstream of the inlet end of the first branch pipe; the fourth valve is provided on the fourth outlet pipe, and is located downstream of the second end of the flow diversion pipe.

7. The method of claim 6, wherein the third outlet pipe is provided with the first fluoride detector and the first calcium ion detector; and the first fluoride detector and the first calcium ion detector are located upstream of the inlet end of the first branch pipe; and
the fourth outlet pipe is provided with the second calcium ion detector; and the second calcium ion detector is located upstream of the first check valve.

8. The method of claim 5, further comprising:
a regenerated water tank;
wherein a permeate side of the first reverse osmosis unit communicates with the regenerated water tank via a first permeate pipe; a permeate side of the second reverse osmosis unit communicates with the regenerated water tank via a second permeate pipe; and
the dilute alkaline wastewater filtration unit comprises a dilute alkaline wastewater conditioning subunit, a second backwashable filter and a nanofiltration subunit; a third booster pump is provided between the second backwashable filter and the nanofiltration subunit; a permeate side of the nanofiltration subunit communicates with the regenerated water tank via a third permeate pipe; and a concentrated water side of the nanofiltration subunit is connected with the silicic acid crystallization unit.

9. The method of claim 3, wherein a top of the conditioning tank communicates with the silicic acid crystallization unit via a gas supply pipe.
